(19) United States
(12) Patent Application Publication
(10) Pub. No.: US 2016/0126216 A1
(43) Pub. Date: May 5, 2016

(54) Method of forming an interconnection and arrangement for a direct interconnect chip assembly

(71) Applicant: Infineon Technologies AG, Neubiberg (DE)

(72) Inventors: Alexander HEINRICH, Bad Abbach (DE); Hermann GRUBER, Woerth a. D. (DE)

(21) Appl. No.: 14/931,021

(22) Filed: Nov. 3, 2015

(30) Foreign Application Priority Data
Nov. 4, 2014 (DE) 10 2014 116 030.4

(51) Int. Cl. H01L 23/00; H01L 21/683

(52) U.S. Cl. CPC H01L 24/83; H01L 24/32; H01L 21/6836; H01L 2224/32258; H01L 2224/32501; H01L 2224/83203; H01L 2224/83894; H01L 2924/01047; H01L 2924/01078; H01L 2924/01046; H01L 2924/01013; H01L 2924/01029; H01L 2924/01079; H01L 2924/01074; H01L 2924/01024; H01L 2924/01042; H01L 2924/01022; H01L 2924/01023; H01L 2924/01028; H01L 2924/3656

(57) ABSTRACT

Various embodiments provide a method of forming an interconnection between an electric component and an electronic component, wherein the method comprises forming a first interconnection sublayer on an electric component, wherein the first interconnection sublayer comprises a metal and has a main surface opposite to the electric component, wherein the main surface has a first surface roughness; forming a second interconnection sublayer on an electronic component, wherein the second interconnection sublayer comprises the metal and has a surface opposite to the electronic component, wherein the surface has a second surface roughness, wherein the first surface roughness and the second surface roughness are in the same order of magnitude; and interconnecting the first interconnection sublayer and the second interconnection sublayer by contacting the same and applying pressure and heat to the contacted first and second interconnection sublayers.

### TECHNICAL FIELD

Various embodiments relate to a method of forming an interconnection, in particular a direct interconnect, and an arrangement for a direct interconnect chip assembly.

### BACKGROUND

Direct-Bonded Copper (DBC) substrates (also called Direct Copper Bonded (DCB) substrates) are used extensively in the power semiconductor industry. A DBC substrate generally includes a thick ceramic substrate member, to which a thinner top plate of copper and a thinner bottom plate of copper are bonded. A semiconductor die includes one or more power devices such as, for example, power transistors and/or power diodes. Metallization on the back side of this semiconductor die is soldered to the top copper plate of the DBC. The DBC is often physically secured by soldering or welding the top copper plate to a package lead. Bond pads on the front side surface of the die are typically wirebonded to other package leads. The resulting assembly is then encapsulated.

From U.S. Pat. No. 8,716,864 B2 aDBA-based power device is known which includes a DBA (Direct Bonded Aluminum) substrate. An amount of silver nanoparticle paste of a desired shape and size is deposited (for example by micro-jet deposition) onto a metal plate of the DBA. The paste is then sintered, thereby forming a sintered silver feature that is in electrical contact with an aluminum plate of the DBA. The DBA is bonded (for example, is ultrasonically welded) to a lead of a leadframe. Silver is deposited onto the wafer back side and the wafer is singulated into dice. In a solderless silver-to-silver die attach process, the silvered back side of a die is pressed down onto the sintered silver feature on the top side of the DBA. At an appropriate temperature and pressure, the silver of the die fuses to the sintered silver of the DBA.

### SUMMARY

Various embodiments provide a method of forming an interconnection between an electric component and an electronic component, wherein the method comprises forming a first interconnection sublayer on an electric component, wherein the first interconnection sublayer comprises a metal and has a main surface opposite to the electric component, wherein the main surface has a first surface roughness; forming a second interconnection sublayer on an electronic component, wherein the second interconnection sublayer comprises the metal and has a surface opposite to the electronic component, wherein the surface has a second surface roughness, wherein the first surface roughness and the second surface roughness are in the same order of magnitude; and interconnecting the first interconnection sublayer and the second interconnection sublayer by contacting the same and applying pressure and heat to the contacted first and second interconnection sublayers.

Furthermore, various embodiments provide a method of forming an interconnection between an electric component and an electronic component, wherein the method comprises forming a first interconnection sublayer on an electric component, wherein the first interconnection sublayer comprises a metal and has a first plasticity; forming a second interconnection sublayer on an electronic component, wherein the second interconnection sublayer comprises the metal and has a second plasticity, wherein the first plasticity and the second plasticity are higher than a plasticity of the electric component and the electronic component; and interconnecting the first interconnection sublayer and the second interconnection sublayer by contacting the same and applying pressure and heat to the contacted first and second interconnection sublayers.

Moreover, various embodiments provide an arrangement for a direct interconnect chip assembly, wherein the arrangement comprises an electric component, comprising a first interconnection sublayer comprising a first metal, arranged on the electric component, and having a main surface opposite to the substrate, wherein the main surface has a first surface roughness; and an electronic component, comprising a second interconnection sublayer comprising the first metal and arranged on the electronic component, and having a surface opposite to the electronic component, wherein the surface has a second surface roughness, wherein the first surface roughness and the second surface roughness are in the same order of magnitude.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A to 1C schematically show a method of interconnecting an electric component and an electronic component according to an exemplary embodiment;

FIGS. 2A to 2C schematically show a method of interconnecting a plurality of electric components and electronic components according to an exemplary embodiment;

FIG. 3 shows a the result of a method according to an exemplary embodiment; and

FIG. 4 shows a flowchart of a method of interconnecting an electric component and an electronic component according to an exemplary embodiment.

### DETAILED DESCRIPTION

In the following further exemplary embodiments of a method of forming an interconnect and an arrangement for a direct interconnect chip assembly will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a solder-free direct interconnect, in particular for power die mounting, wherein the interconnect is formed by contacting and/or interconnecting a first interconnection sublayer formed on a first electric component and a second interconnection sublayer formed on a second electric component by bringing the two interconnection sublayers in contact and subject the contacted interconnection sublayers to pressure and/or heat. Both of the interconnection sublayers may comprise or may consist of the same interconnection material, e.g. a metal, like silver, gold, platinum, palladium, aluminum or copper. One of the interconnection sublayers may have a pointed surface while the other one may have a higher plasticity (in particular malleability and/or ductility) than the one interconnection sublayer (having the pointed surface). Optionally the two interconnection sublayers may have a surface roughness and/or waviness which is in the same order of magnitude.

In particular, no solder, no sintering paste or other similar adhesive may be used when contacting and interconnecting the two interconnection sublayers with each other, i.e. the interconnection process may be a solder-free interconnection process. It should be noted that the metal of the two sublayers is preferably the same, so that a fusing by diffusion is eased. In particular, the first interconnection sublayer may have a thickness in the range between 1 micrometer and 10 micrometer, preferably between 1.5 micrometer and 5 micrometer, e.g. between 2 micrometer and 3 micrometer. In particular, the second interconnection sublayer may have a thickness in the range between 100 nanometer and 500 nanometer, preferably between 150 nanometer and 300 nanometer, e.g. 200 nanometer.

In particular, the first and second surface roughness may be in the range of 500 nm to 10 micrometer measured as mean peak to peak distance, preferably in the range of 1 micrometer to 5 micrometer, e.g. in the range of 2 to 3 micrometer. In particular, the term “same order of magnitude” may denote the fact that the surface roughness differ at most by a factor of 5, preferably at most by a factor of 2.5, e.g. by a factor of 2.

In particular, one of the interconnect sublayers may have a malleability which is higher than the malleability of the other of the interconnect sublayers. A good malleable material in this perspective should no exhibit a Vickers hardness or Brinell Hardness greater than 5 GPa, preferably lower than 2.5 GPa, e.g. less than 1 GPa.

It should be noted that the term “electrical component” has to be taken in a broad sense, i.e. should encompass any (at least partially) electrically conductive component or element, like a substrate, carrier, leadframe (comprising or consisting of copper; FeNi, so-called alloy42, Mo, MoCu, or the like), DCB, DAB or the like and as well electronic components, like chips, integrated circuits, (semiconductor) dies, or the like.

By providing two interconnection sublayers having a surface roughness of the same order of magnitude it may be possible that after interconnecting the two sublayers the ready interconnection may exhibit a high electrical and/or thermal conductivity and/or strength, e.g. by reducing the number of voids arising during connecting the two interconnection sublayers. In particular, when providing two interconnection sublayers having different levels of plasticity (in particular, ductility or malleability) it may be possible that in a first contacting step (under applying pressure force) the less ductile sublayer (e.g. a pointed one) penetrates the other more ductile sublayer, so that some kind of form fit or positive fit may be achievable. In a second step or stage (heating) a diffusion process may be performed resulting in a good electrical and/or thermal contacting even when the heating is only up to a temperature below the melting temperature of the metal or interconnect material. It should be noted that it may also be possible to initially perform the heating step (to a temperature below the melting point) and afterwards to contact the both interconnection sublayers while applying pressure to the same. Due to the provision of a solder-free process or method it may be possible to apply the best possible design rules, since no or only very few squeeze out of material may be present. Furthermore, no processing of the backside or backend of the electronic components may be necessary and the second interconnection sublayer may be formed on a standard rough backside, e.g. a three layer backside including a barrier layer.

In the following exemplary embodiments of the method of forming an interconnection are described. However, the features and elements described with respect to these embodiments can be combined with exemplary embodiments of the arrangement or set for a direct interconnect chip assembly.

According to an exemplary embodiment of the method the electric component and the electronic component have a plasticity which is lower than the plasticity of the first interconnection sublayer and second interconnection sublayer.

In other words the electronic component and the electric component may both be harder or less ductile than the sublayers of the interconnection layer. It should be noted that in particular, the portions of the electric component and/or the electronic component on which the first interconnection sublayer and the second interconnection layer, respectively are arranged or deposited may be less ductile than the respective interconnection sublayers. By providing interconnection sublayers on the components to be interconnected having a higher plasticity (malleability) than the components below it may be possible to ensure that primarily the interconnection sublayers may be deformed when pressure is applied during the interconnection process or step.

According to an exemplary embodiment of the method the first interconnection sublayer and the second interconnection sublayer have a different plasticity.

For example, one of the interconnection sublayers may comprise or may (at least partially) consists of a monocrystalline metal, e.g. silver, while the other one may comprise or (at least partially) consist of a microcrystalline metal, e.g. silver. For example, the microcrystalline layer may be formed by sputtering while the monocrystalline layer may be formed by an electrochemical plating process.

By providing interconnection sublayers having different plasticity it may be possible that during the contacting step the one sublayer having the lower plasticity or higher hardness penetrates the other interconnection sublayer having the higher plasticity so that already due to the pressure a kind of form fit or positive fit may be achievable to some extend which may increase the interconnection quality.

According to an exemplary embodiment of the method the electric component is one element out of the group consisting of: a substrate; a carrier; a leadframe; a semiconductor wafer; a chip; a (semiconductor) die; and a chip package. In particular, the semiconductor wafer, the chip and the die may comprise or predominantly consist of silicon and/or III-V or II-VI compound semiconductor material.

For example, the second interconnection sublayer may be formed on the backside of the electronic component, e.g. chip or die. It should be noted that the electronic component may comprise a plurality or array of single chips or dies or a plurality of electronic components may be interconnected in a batch process. Furthermore, it should be noted that more than the described two components may be stacked on each other, e.g. a stack may be formed comprising two electric components and one or two electronic components. In general a plurality of pairs of electric components and electronic components may be stacked on top of each other using the described interconnection method.

According to an exemplary embodiment of the method the first interconnection sublayer comprises a plurality of electrically separated portions.

In particular, the electric component, e.g. a carrier or substrate, may form a carrier for a fine pitch interconnection of a power die mounting or the like. Due to the use of a solder-free interconnection it may be possible to provide an interconnection having a fine pitch, since no solder is squeezed out when forming the interconnection. Thus, it may also possible to use or apply the best possible design rules.

According to an exemplary embodiment of the method at least one of the first interconnection sublayer and the second interconnection sublayer are formed by a process selected out of the group consisting of: sputtering, physical vapor deposition, plating, electro plating, evaporation, and electrochemical plating.

In particular, electrochemical plating may be a suitable process for forming at least one of the interconnection sublayers, since the dimensions, thickness and/or roughness of the same may be controllable by adjusting pulse form, pulse width and/or pulse length. However, it should be noted that preferably the forming of the first and second interconnection sublayer may not comprise a sintering step, i.e. the forming of these sublayers may be a sintering-free process, in particular, the whole interconnection method may be free of any sintering steps or processes involving individual particles.

According to an exemplary embodiment of the method the first interconnection sublayer and the second interconnection sublayer are formed by different processes.

In particular, one of the interconnection sublayers may be formed by sputtering while the other one may be formed by a plating process, e.g. an electro or electrochemical plating process. The use of different processes may be an efficient way to provide interconnection sublayers having a different level of plasticity.

According to an exemplary embodiment of the method the second interconnection sublayer is formed on a plurality of electronic components.

In particular, the plurality or array of electronic components may comprise or may consists of housed or unhoused integrated circuits (e.g. power transistors, power diodes, power modules or the like), (semiconductor) dies or the like. Thus, the interconnection method may form a batch process in which a plurality of single electronic components or elements, e.g. dies, may be connected in a single process step. Alternatively, the electronic component may comprise or may be formed by a single electronic component, e.g. a (power) die.

The electric component may be a carrier or leadframe, for example.

According to an exemplary embodiment of the method during the interconnection the interconnection sublayers are heated to a temperature below a melting point of the metal.

In particular, during the whole interconnection process the temperature is always kept below the melting point or melting temperature of the metal or interconnect material. Thus, it may be possible to avoid or at least drastically reduce the amount of melting and/or squeezing out of metal of the interconnection sublayers during the interconnection process. In particular, the interconnection process may be a cold or solid-solid diffusion interconnection process or step.

According to an exemplary embodiment the method further comprises forming a barrier layer between the electronic component and the second interconnection sublayer and comprising at least one material selected out of the group consisting of: tungsten, chromium, molybdenum, titanium, vanadium, and nickel.

According to an exemplary embodiment the method further comprises attaching at least one of the electric component and the electronic component to a transfer tape before interconnecting the first and the second interconnection sublayers.

In particular, the electronic component or a plurality of electronic components may be attached to one transfer tape. Preferably the transfer tape is attached to the front side of the electronic component. Additionally, the electric component or a plurality of electric components may be optionally attached to another transfer tape.

According to an exemplary embodiment the method further comprises removing the transfer tape after interconnecting the first and the second interconnection sublayers.

According to an exemplary embodiment of the method the metal is one out the group consisting of: silver, copper, and gold.

According to an exemplary embodiment of the method at least one of the first interconnection sublayer and the second interconnection sublayer comprises a pointed surface.

In particular, one of the both interconnection sublayers may have a pointed surface. For example, the pointed surface may be formed on the electronic component, e.g. a backside of a chip or die.

In particular, it should be noted that the interconnection method may be a solder-free method and/or that the first and second interconnection sublayer may be formed without a sintering step.

In the following exemplary embodiments of the arrangement or set for a direct interconnect chip assembly are described. However, features described with respect to these embodiments can be combined with exemplary embodiments of the method of forming an interconnection between an electric component and an electronic component.

According to an exemplary embodiment the arrangement further comprises a plurality of electronic components each comprising a second interconnection sublayer.

In particular, the plurality of electronic components, e.g. (power) transistors, (power) diodes, or the like, may form or build an array of electronic components or elements.

According to an exemplary embodiment the arrangement further comprises a transfer tape.

In particular, the electronic component or a plurality of electronic components may be attached or mounted to the transfer tape. Alternatively, the (front side of the) electric component or a plurality of electric components may be attached to the transfer tape. Optionally, the electronic component(s) and the electric component(s) are attached to a first and second transfer tape, respectively.

According to an exemplary embodiment of the arrangement the malleability of the first interconnect sublayer is higher than the malleability of the second interconnect sublayer.

According to an exemplary embodiment of the arrangement the electric component and the electronic component are interconnected to each other by applying pressure and heat.

In particular, the first interconnection sublayer and the second interconnection sublayer may be interconnected to each other. Thus, it may be possible that the arrangement forms a stack of two components, i.e. the electric component and the electronic component interconnected to each other. Such a stack may form an electronic module, a chip package or the like.

According to an exemplary embodiment the arrangement further comprising at least a further electric component which is stacked on the electronic component.

In particular, a plurality of further electric component(s) and/or further electronic components may be provided. Thus, a stack may be formed comprising a plurality of electronic components and electric components. That is, it is readily possible, to interconnect more than two components stacked above each other.

In the following specific embodiments of the method of forming an interconnection between an electric component and an electronic component will be described in more detail with respect to the figures.

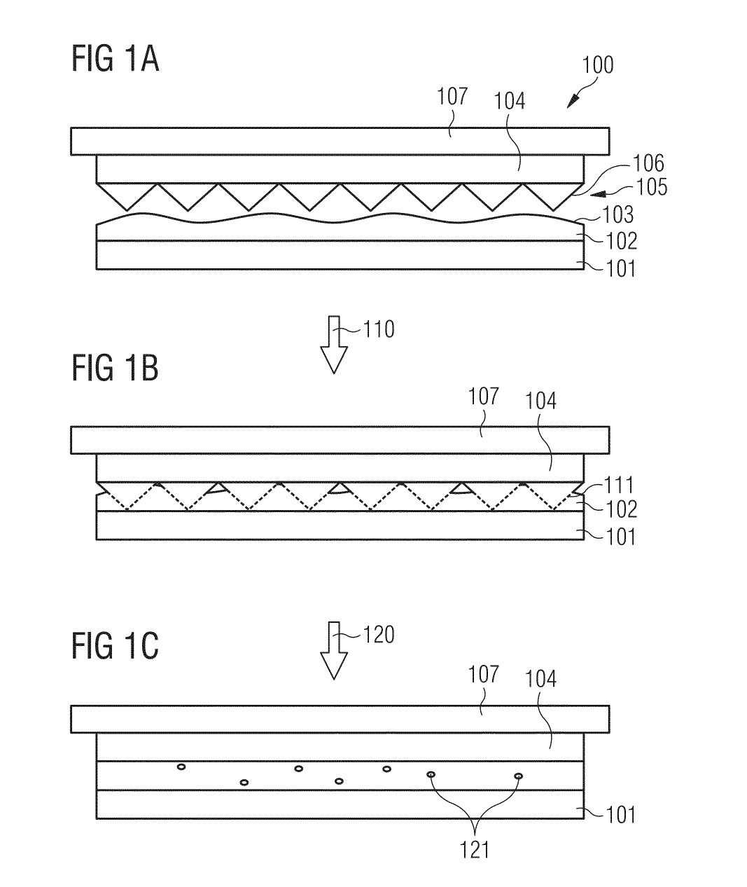

FIGS. 1A to 1C schematically illustrate a method of interconnecting an electric component and an electronic component 100 according to an exemplary embodiment. In particular, FIG. 1A shows an electric component, e.g. a leadframe or carrier, chip or die, 101, on which a first interconnection sublayer 102, comprising or consisting of a metal or interconnection material, e.g. silver, gold or copper, is formed, wherein silver may be preferred due to its high thermal and electrical conductivity which may enable a significant miniaturization potential. Furthermore, the use of silver may enable reduction of process costs and reduced stress potential when compared to known AuSn (gold-tin) diffusion solder processes. In addition the use of silver may reduce potential issues with unreacted Sn due to reflow in a tin-rich solder system using CuSn intermetallic phases (copper-tin). The first interconnection sublayer 101 has surface structures 103 (schematically indicated by an undulating surface) resulting in a surface roughness.

Furthermore, FIG. 1A shows an electronic component 104, e.g. a chip, die or the like, on which a second interconnection sublayer 105, comprising or consisting of the same metal as the first interconnection sublayer 102, is formed. The second interconnection sublayer 105 has surface structures 106 (schematically indicated by a pointing surface) resulting in a surface roughness, wherein the surface roughness of the sublayers is in the same order of magnitude.

For example, the second interconnection sublayer may be formed by a sputtering process to the backside of the electronic component leading to a fine- or microcrystalline structure, while the first interconnection sublayer may be formed by a plating process, e.g. an electrochemical plating process, which may result in a more ductile (e.g. monocrystalline) structure than the sputtered second interconnection sublayer. The first interconnection sublayer may form a coating on the electric component and/or the second interconnection sublayer may form a coating on the electronic component.

Moreover, FIG. 1A shows a transfer tape 107 to which the electronic component 104 is attached or mounted to at its front side. Also the electric component 101 may be attached to a transfer tape although this is not shown in FIG. 1A.

FIG. 1B illustrates a subsequent step of the method, in which the two interconnection sublayers 102 and 105 are brought into contact by applying a pressure force (indicated by arrow 110). This may be done by subjecting the stack shown in FIG. 1A to a heated press. Due to the pressure applied and the pointed surface of the second interconnection sublayer 105 the same deforms and penetrates into the first interconnection sublayer. Thus, the two interconnection sublayers may be brought into good contact by cold working of a more ductile first interconnection sublayer (first stage). It should be noted that no solder is added or applied in the method or process depicted in FIG. 1, i.e. the described method is a solder-free method or process.

FIG. 1C illustrates a subsequent step of the method, in which an interdiffusion step takes place. The interdiffusion in the sublayers 102 and 105 is promoted by an increase of the temperature and advances over time which is indicated by the arrow 120. In particular, the interdiffusion has the effect that the former boundary (indicated by the dotted line 111 in FIG. 1B) disappears and the former two interconnection sublayers form a single interconnection layer (second stage). Schematically some voids 121 are indicated in FIG. 1C. The heating may be performed under reduced pressure or vacuum, and preferably the heating is restricted to a temperature which is below the melting point of the material of the interconnection sublayers.

It should be noted that already the electric component 101 may be an electronic component, e.g. chip or die, so that a chip-to-chip connection or interconnect is formed by the depicted method. In addition, the method may also be used for fine pitch interconnection between an electric and electronic component or an electronic component and a further electronic component, due to the avoiding of squeeze out of solder or interconnection material in the solder-free process. Also a ratio of chip size to die size can be chosen arbitrarily, due to an absence of squeeze out of solder.

In addition it should be noted that the described process steps can be done with one electronic component being connected to an electric component at one time, e.g. by heating the electric component to the desired temperature below the melting temperature of the interconnect material and then pressing the single electronic component to it.

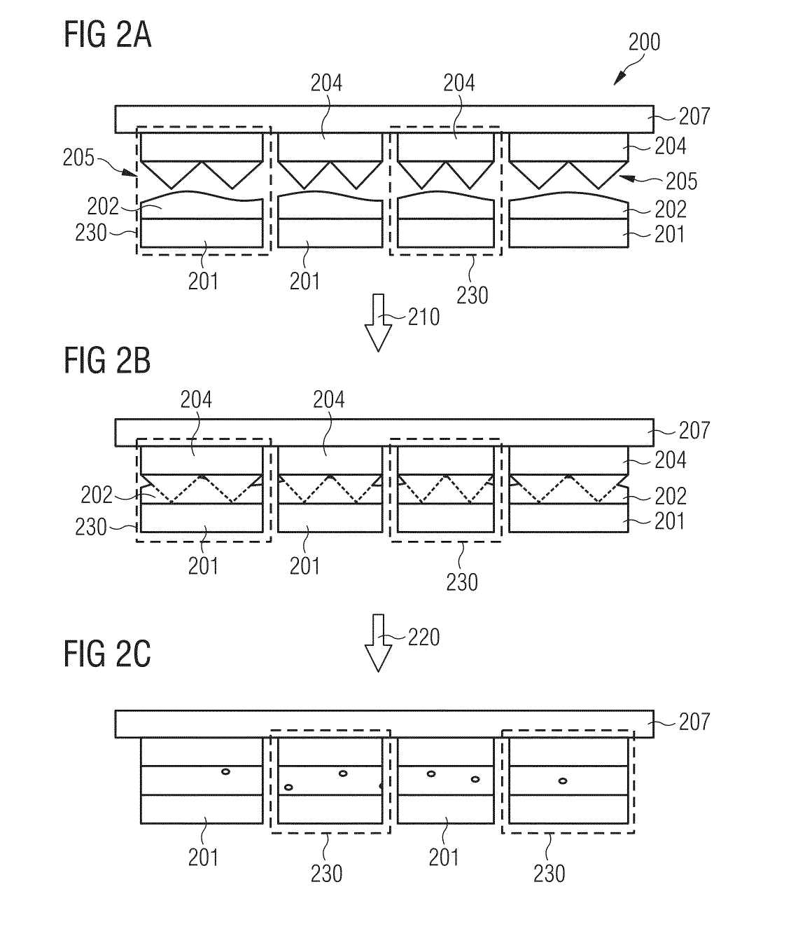

FIGS. 2A to 2C schematically illustrate a method of interconnecting a plurality of electric components and electronic 200 components according to an exemplary embodiment. In particular, FIG. 2A to 2C illustrates a so-called Batch Die Attach (BDA) process, which is similar to the process shown in FIG. 1A to 1C. In principle the difference to the solid-solid interconnection process of FIG. 1A to 1C is that the BDA process involves a plurality of stacks 230 comprising electric components 201, first interconnection sublayers 202, electronic components 204 and second interconnection sublayers 205, wherein the second interconnection sublayers are attached or mounted to a backside of the electronic components 204. After forming the stacks and attaching the electronic components to a transfer tape 207 the same two stage process as depicted in FIGS. 1B and 1C is performed and indicated in FIGS. 2B and 2C by the arrows 210 and 220.

After the annealing at a moderate temperature, i.e. below the melting point of the interconnection material, the transfer tape may be removed, the stacks or electronic assemblies may be singulated and the frontend contacts may be mounted to the front side or frontend of the electronic components 204. It should be noted that no changes or adaptations of the frontend materials may be necessary, when performing the process schematically depicted in FIG. 1 or FIG. 2.

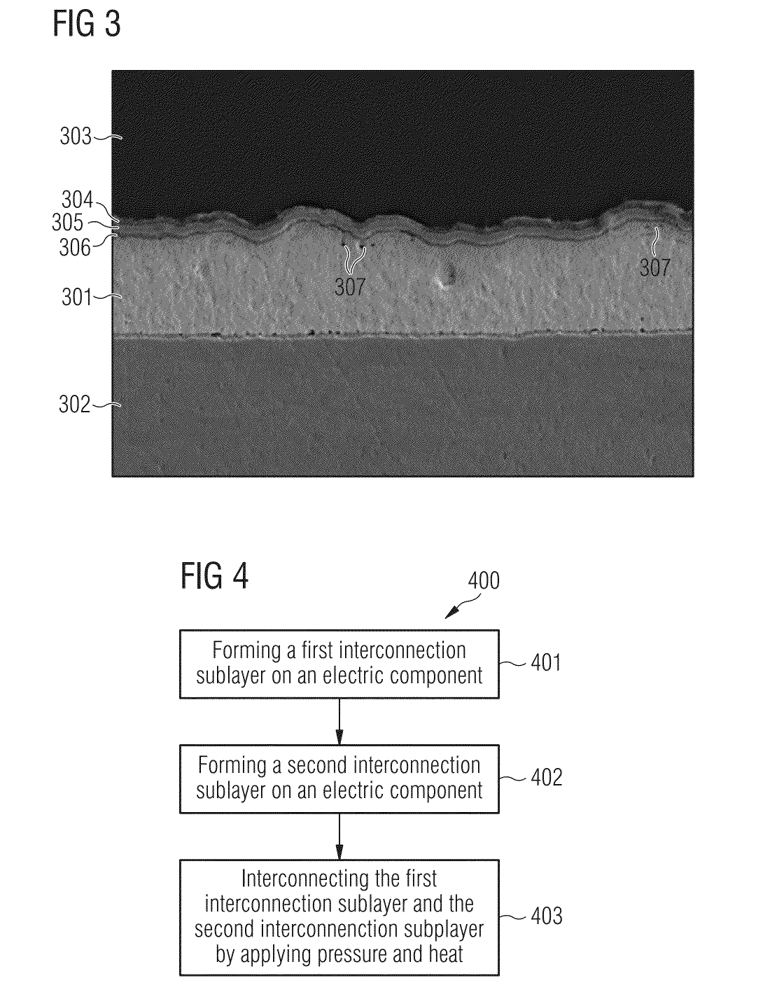

FIG. 3 shows a result of a method according to an exemplary embodiment. In particular, FIG. 3 shows a microscopic image of an interconnection layer 301 of silver formed by an interdiffusion interconnection step between an electric component, e.g. leadframe, 302, and an electronic component, e.g. 303, die. In addition several intermediate layers 304, 305, and 306 of titanium, tungsten, chromium, molybdenum and nickel are shown between the interconnection layer 301 and the backside of the electronic component 303. As can be seen in FIG. 3 only very few voids 307 are formed during the interdiffusion process at the bond line and no border line or interface between the two interconnection sublayers can be seen any longer.

FIG. 4 shows a flowchart of a method of interconnecting an electric component and an electronic component 400 according to an exemplary embodiment. In particular, the method 400 comprises forming a first interconnection sublayer on an electric component (step 401), wherein the first interconnection sublayer comprises a metal and has a main surface opposite to the electric component, wherein the main surface has a first surface roughness. Furthermore, the method comprises forming a second interconnection sublayer on an electronic component (step 402), wherein the second interconnection sublayer comprises the metal and has a surface opposite to the electronic component, wherein the surface has a second surface roughness, wherein the first surface roughness and the second surface roughness are in the same order of magnitude. Afterwards an interconnection step 403 interconnecting the first interconnection sublayer and the second interconnection sublayer by contacting the same and applying pressure and heat to the contacted first and second interconnection sublayers is applied.

Optionally, a transfer tape may be attached to the front side of the electronic component and/or to the electric component. Furthermore, it should be noted that additional layers, e.g. barrier layers, may optionally be formed between the electronic component and the second interconnection sublayer.

It should be noted that it is readily possible to interconnect more than two components stacked above each other in the same way as it is described. For example, for an assembly with an electronic component arranged between two electric components the electric component preferably then exhibit the described layer structure and an interconnection sublayer on both sides opposite the interconnection sublayers of the electric components on top and bottom of the electronic component.

It should also be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of forming an interconnection between an electric component and an electronic component, the method comprising:
forming a first interconnection sublayer on an electric component, wherein the first interconnection sublayer comprises a metal and has a main surface opposite to the electric component, wherein the main surface has a first surface roughness;
forming a second interconnection sublayer on an electronic component, wherein the second interconnection sublayer comprises the metal and has a surface opposite to the electronic component, wherein the surface has a second surface roughness, wherein the first surface roughness and the second surface roughness are in the same order of magnitude, and
interconnecting the first interconnection sublayer and the second interconnection sublayer by contacting the same and applying pressure and heat to the contacted first and second interconnection sublayers.

2. The method according to claim 1, wherein the electric component and the electronic component have a plasticity which is lower than the plasticity of the first interconnection sublayer and second interconnection sublayer.

3. The method according to claim 1, wherein the first interconnection sublayer and the second interconnection sublayer have a different plasticity.

4. The method according to claim 1, wherein the electric component is one element out of the group consisting of:
a substrate;
a carrier;
a leadframe;
a semiconductor wafer;
a chip;
a die; and
a chip package.

5. The method according to claim 1, wherein the first interconnection sublayer comprises a plurality of electrically separated portions.

6. The method according to claim 1, wherein at least one of the first interconnection sublayer and the second interconnection sublayer are formed by a process selected out of the group consisting of:
sputtering,
physical vapor deposition,
plating,
electro plating, evaporation, and
electrochemical plating.

7. The method according to claim 1, wherein the first interconnection sublayer and the second interconnection sublayer are formed by different processes.

8. The method of claim 1, wherein the second interconnection sublayer is formed on a plurality of electronic components.

9. The method according to claim 1, wherein during the interconnection the interconnection sublayers are heated to a temperature below a melting point of the metal.

10. The method according to claim 1, further comprising forming a barrier layer between the electronic component and the second interconnection sublayer and comprising at least one material selected out of the group consisting of:
tungsten,
chromium,
molybdenum,
titanium,
vanadium, and
nickel.

11. The method according to claim 1, further comprising attaching at least one of the electric component and the electronic component to a transfer tape before interconnecting the first and the second interconnection sublayers.

12. The method according to claim 11, further comprising removing the transfer tape after interconnecting the first and the second interconnection sublayers.

13. A method of forming an interconnection between an electric component and an electronic component, the method comprising:
forming a first interconnection sublayer on an electric component, wherein the first interconnection sublayer comprises a metal and has a first plasticity;
forming a second interconnection sublayer on an electronic component, wherein the second interconnection sublayer comprises the metal and has a second plasticity, wherein the first plasticity and the second plasticity are higher than a plasticity of the electric component and the electronic component; and
interconnecting the first interconnection sublayer and the second interconnection sublayer by contacting the same and applying pressure and heat to the contacted first and second interconnection sublayers.

14. The method according to claim 13, wherein the metal is one out the group consisting of:
silver,
platinum,
palladium,
aluminum
copper, and
gold.

15. The method according to claim 13, wherein at least one of the first interconnection sublayer and the second interconnection sublayer comprises a pointed surface.

16. An arrangement for a direct interconnect chip assembly, the arrangement comprising:
an electric component comprising a first interconnection sublayer comprising a first metal, arranged on the electric component, and having a main surface opposite to the substrate, wherein the main surface has a first surface roughness,
an electronic component, comprising a second interconnection sublayer comprising the first metal and arranged on the electronic component, and having a surface opposite to the electronic component, wherein the surface has a second surface roughness,
wherein the first surface roughness and the second surface roughness are in the same order of magnitude.

17. The arrangement of claim 16, further comprising a plurality of electronic components each comprising a second interconnection sublayer.

18. The arrangement of claim 16, wherein the malleability of the first interconnect sublayer is higher than the malleability of the second interconnect sublayer.

19. The arrangement according to claim 16, wherein the electric component and the electronic component are interconnected to each other by applying pressure and heat.

20. The arrangement according to claim 19, further comprising at least a further electric component which is stacked on the electronic component.
